(19) United States
(12) Patent Application Publication
(10) Pub. No.: US 2022/0180595 A1
(43) Pub. Date: Jun. 9, 2022

(54) SYSTEM AND METHOD FOR CREATING THREE-DIMENSIONAL RENDERINGS OF ENVIRONMENTS FROM TWO-DIMENSIONAL IMAGES

(71) Applicant: Boom Interactive, Inc., Salt Lake City, UT (US)

(72) Inventors: Satish Reddy Bethi, Salt Lake City, UT (US); Jeremiah Timberline Barker, Sandy, UT (US)

(21) Appl. No.: 17/678,384

(22) Filed: Feb. 23, 2022

Related U.S. Application Data
(63) Continuation-in-part of application No. 16/900,500, filed on Jun. 12, 2020.

(51) Int. Cl. G06T 15/08; G06T 15/00; G06F 30/13; G06N 20/20

(52) U.S. Cl. CPC G06T 15/08; G06N 20/20; G06F 30/13; G06T 15/005

(57) ABSTRACT

A system and method for creating three-dimensional environments from two-dimensional images, comprising inputting a two-dimensional image of a floorplan into a pre-processing component that resizes the image, normalizes the image, and then generates an output of the image; inputting the output of the pre-processing component into an artificial intelligence component that generates bounding boxes having predefined classes of items corresponding to various floorplan icons; a semantic map classifying room structures; and a semantic map classifying room types, and then generates an output of the bounding boxes and semantic maps; and inputting the output of the artificial intelligence component into a post-processing component that processes the classified bounding boxes for each predefined class of item; processes the semantic map for each structure; processes the semantic map for each room-type; converts dimensions from pixel coordinates to real-world estimates; packages and encodes data for a three-dimensional environment; and then generates an output of the three-dimensional environment.

### CROSS-REFERENCE TO RELATED APPLICATIONS

This patent application is a continuation-in-part of U.S. patent application Ser. No. 16/900,500 filed on Jun. 12, 2020 and entitled “Data Serialization Extrusion for Converting Two-Dimensional Images to Three-Dimensional Geometry”, the disclosure of which is hereby incorporated by reference herein in its entirety and made part of the present U.S. utility patent application for all purposes.

### BACKGROUND

The disclosed technology relates in general to computer software and software- based systems for processing images, and more specifically to systems, methods, and devices for creating images of three-dimensional environments from two-dimensional images using an extrusion algorithm that includes an artificial intelligence component or module.

The design and construction of interior rooms within houses and other living environments, and individual rooms and offices within commercial and industrial buildings is very often a time-consuming, laborious, and very expensive process. Various computer or software- based modeling products currently exist for assisting with such projects; however, these products are often expensive, difficult to use, and require specific training on the part of architects, designers, and other users of such products. Accordingly, a software-based product capable of rapidly and easily converting a two-dimensional image such as a photograph of a room or a drawing of a floorplan into an accurate three-dimensional environment completely populated with furnishings of choice would be highly advantageous.

### SUMMARY

The following provides a summary of certain example implementations of the disclosed technology. This summary is not an extensive overview and is not intended to identify key or critical aspects or elements of the disclosed technology or to delineate its scope. However, it is to be understood that the use of indefinite articles in the language used to describe and claim the disclosed technology is not intended in any way to limit the described technology. Rather the use of “a” or “an” should be interpreted to mean “at least one” or “one or more”.

One implementation of the disclosed technology provides a system for creating three-dimensional environments from two-dimensional images, comprising a pre-processing component configured to receive an input of a two-dimensional image of a floorplan, resize the image, normalize the image, and then generate an output of the image; an artificial intelligence component configured to receive the output of the pre-processing component and generate bounding boxes having predefined classes of items corresponding to various floorplan icons; a semantic map classifying room structures; and a semantic map classifying room types, and then generate an output of the bounding boxes and semantic maps; and a post-processing component configured to receive the output of the artificial intelligence component and process the classified bounding boxes for each predefined class of item; process the semantic map for each structure; process the semantic map for each room-type; convert dimensions from pixel coordinates to real- world estimates; package and encode data for a three-dimensional environment; and then generate an output of the three-dimensional environment.

The artificial intelligence component may include a generative adversarial neural network that further includes both a generator network and an adversarial network. The generator network may include a feature encoder, first and second spatial context modules, detection layers, and first and second feature decoders. The adversarial network may include first and second discriminators. The predefined classes of items corresponding to various floorplan icons may include furnishings, countertops, and appliances. The room structures include walls, doors, and windows. The room types include offices, conference rooms, living areas, dining areas, kitchens, and bedrooms. The post-processing component may create geometric vectors and polygons in real-world measurements for the three-dimensional environment. Processing classified bounding boxes for each predefined class of item may include obtaining spatial information for each predefined class of item in terms of pixel coordinates. Processing a semantic map for each room structure may include taking the pixels from the semantic map of all of the structures as input and providing vectors as output. Processing a semantic map for each room type may include using all pixels from the sematic map of all the room-types and the vectors from the semantic maps of each structure and creating room polygons. Converting dimensions from pixel coordinates to real-world estimates may include converting spatial information for all the predefined classes, structures, vectors, and room-polygons from pixel coordinates to real-world coordinates.

Another implementation of the disclosed technology provides a method for creating three-dimensional environments from two-dimensional images, comprising inputting a two- dimensional image of a floorplan into a pre-processing component that resizes the image, normalizes the image, and then generates an output of the image; inputting the output of the pre- processing component into an artificial intelligence component that generates bounding boxes having predefined classes of items corresponding to various floorplan icons; a semantic map classifying room structures; and a semantic map classifying room types, and then generates an output of the bounding boxes and semantic maps; and inputting the output of the artificial intelligence component into a post-processing component that processes the classified bounding boxes for each predefined class of item; processes the semantic map for each structure; processes the semantic map for each room-type; converts dimensions from pixel coordinates to real-world estimates; packages and encodes data for a three-dimensional environment; and then generates an output of the three-dimensional environment.

The artificial intelligence component may include a generative adversarial neural network that further includes both a generator network and an adversarial network. The generator network may include a feature encoder, first and second spatial context modules, detection layers, and first and second feature decoders and the adversarial network may include first and second discriminators. The predefined classes of items corresponding to various floorplan icons may include furnishings, countertops, and appliances. The room structures include walls, doors, and windows. The room types include offices, conference rooms, living areas, dining areas, kitchens, and bedrooms. The post-processing component may create geometric vectors and polygons in real-world measurements for the three-dimensional environment. Processing classified bounding boxes for each predefined class of item may include obtaining spatial information for each predefined class of item in terms of pixel coordinates. Processing a semantic map for each room structure may include taking the pixels from the semantic map of all of the structures as input and providing vectors as output. Processing a semantic map for each room type may include using all pixels from the sematic map of all the room-types and the vectors from the semantic maps of each structure and creating room polygons. Converting dimensions from pixel coordinates to real-world estimates may include converting spatial information for all the predefined classes, structures, vectors, and room-polygons from pixel coordinates to real-world coordinates.

Still another implementation of the disclosed technology provides another method for creating three-dimensional environments from two-dimensional images, comprising inputting a two-dimensional image of a floorplan into a pre-processing component that resizes the image, normalizes the image, and then generates an output of the image; inputting the output of the pre- processing component into an artificial intelligence component, wherein the artificial intelligence component generates bounding boxes having predefined classes of items corresponding to various floorplan icons; a semantic map classifying room structures; and a semantic map classifying room- types, and then generates an output of the bounding boxes and semantic maps, wherein the artificial intelligence component includes a generative adversarial neural network that includes a generator network having a feature encoder, first and second spatial context modules, detection layers, and first and second feature decoders, and an adversarial network having first and second discriminators; and inputting the output of the artificial intelligence component into a post- processing component, wherein the post-processing component processes the classified bounding boxes for each predefined class of item; processes the semantic map for each structure; processes the semantic map for each room-type; converts dimensions from pixel coordinates to real-world estimates; packages and encodes data for a three-dimensional environment; and then generates an output of the three-dimensional environment.

The predefined classes of items corresponding to various floorplan icons may include furnishings, countertops, and appliances. The room structures include walls, doors, and windows. The room types include offices, conference rooms, living areas, dining areas, kitchens, and bedrooms. The post-processing component may create geometric vectors and polygons in real- world measurements for the three-dimensional environment. Processing classified bounding boxes for each predefined class of item may include obtaining spatial information for each predefined class of item in terms of pixel coordinates. Processing a semantic map for each room structure may include taking the pixels from the semantic map of all of the structures as input and providing vectors as output. Processing a semantic map for each room type may include using all pixels from the sematic map of all the room-types and the vectors from the semantic maps of each structure and creating room polygons. Converting dimensions from pixel coordinates to real-world estimates may include converting spatial information for all the predefined classes, structures, vectors, and room-polygons from pixel coordinates to real-world coordinates.

It should be appreciated that all combinations of the foregoing concepts and additional concepts discussed in greater detail below (provided such concepts are not mutually inconsistent) are contemplated as being part of the technology disclosed herein and may be implemented to achieve the benefits as described herein. Additional features and aspects of the disclosed system, devices, and methods will become apparent to those of ordinary skill in the art upon reading and understanding the following detailed description of the example implementations. As will be appreciated by the skilled artisan, further implementations are possible without departing from the scope and spirit of what is disclosed herein. Accordingly, the drawings and associated descriptions are to be regarded as illustrative and not restrictive in nature.

### BRIEF DESCRIPTION OF THE DRAWINGS

The accompanying drawings, which are incorporated into and form a part of the specification, schematically illustrate one or more example implementations of the disclosed technology and, together with the general description given above and detailed description given below, serve to explain the principles of the disclosed subject matter, and wherein:

FIG. 1 is a flowchart depicting an extrusion process in accordance with an example implementation of the disclosed technology, wherein the extrusion process includes obtaining a floorplan image, pre-processing the image, processing the image using an artificial intelligence (AI) module; post-processing various outputs from the AI module; and generating a three- dimensional rendering of an environment derived from the floorplan image;

FIG. 2 is a flowchart depicting a pre-processing framework in accordance with an example implementation of the disclosed technology;

FIG. 3 is a flowchart depicting an AI framework in accordance with an example implementation of the disclosed technology; and

FIG. 4 is a flowchart depicting a post-processing framework in accordance with an example implementation of the disclosed technology.

### DETAILED DESCRIPTION

Example implementations are now described with reference to the Figures. Reference numerals are used throughout the detailed description to refer to the various elements and structures. Although the following detailed description contains many specifics for the purposes of illustration, a person of ordinary skill in the art will appreciate that many variations and alterations to the following details are within the scope of the disclosed technology. Accordingly, the following implementations are set forth without any loss of generality to, and without imposing limitations upon, the claimed subject matter.

The disclosed technology utilizes an extrusion algorithm for analyzing a two- dimensional floorplan image and extracting useful information such as, for example, walls, windows, doors, furnishings (e.g., furniture, fittings, and other decorative accessories, such as curtains and carpets), cabinets, room-polygons, room-types and then creating a three-dimensional rendering of an environment based on this information. The extrusion algorithm includes three basic aspects, steps, or components: (a) a pre-processing; (b) an AI module; and (c) post-processing. The AI module analyzes a floorplan and recognizes structures (e.g., walls, doors, and windows), room-types, room-boundaries, and classified bounding boxes for furnishings. Semantic map outputs from the AI module are converted into vectors for each structure. The vectorization process also detects any shaped structures including diagonal and circular structures. Additionally, in post-processing, new vectors that weren't detected by the AI module along room boundaries are estimated and created to provide a more enclosed floor plan. This assists with building better room- polygons which in turn provide additional important information regarding rooms (e.g., square footage and bounding structures). Finally, real-world dimensions are estimated for structures, rooms, and furnishings.

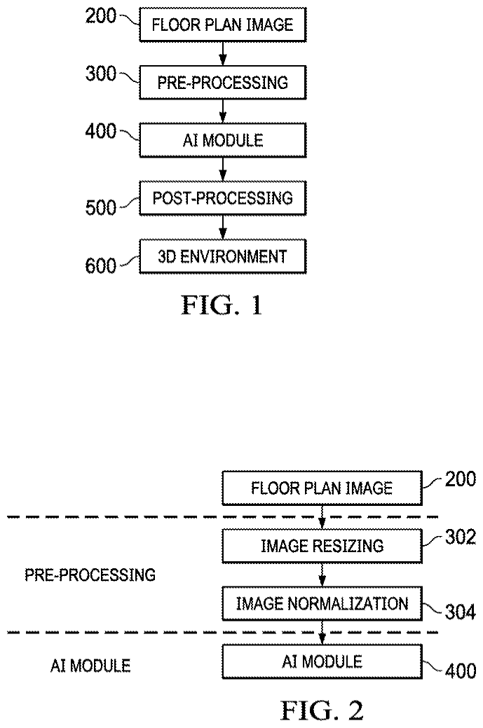

FIG. 1 provides a flowchart depicting an extrusion process in accordance with an example implementation of the disclosed technology, wherein the extrusion process includes obtaining a floorplan image, pre-processing the image, processing the image using an artificial intelligence (AI) module; post-processing various outputs from the AI module; and generating a three-dimensional rendering of an environment derived from the floorplan image. With reference to FIG. 1, example extrusion process 100 consists of obtaining floorplan image 200; pre-processing floorplan image 200 at step 300; analyzing the pre-processed floorplan image using AI module 400; post-processing raw outputs from AI module 400 at step 500; and creating a three-dimensional environment using the processed outputs from the post-processing step 500 at step 600.

FIG. 2 provides a flowchart depicting a pre-processing framework in accordance with an example implementation of the disclosed technology. With reference to FIG. 2, in pre-processing floorplan image 200 at step 300 the input image (e.g., a floorplan) is morphed and formatted as required by AI module 400. Pre-processing includes two aspects: image resizing step 302; and image normalization step 304. At image-resizing step 302, the image is resized such that its longer dimension is scaled to a desired resolution (e.g., 512) while preserving the aspect ratio of the image. This resized image is then padded on both sides along the shorter dimension to achieve a square resolution (e.g., 512×512). The padding value is then set to the approximate background color of the original image. At image normalization step 304, a mean removal is performed on the resized square image which is followed by image normalization where all the pixel values are regulated between 0 and 1.

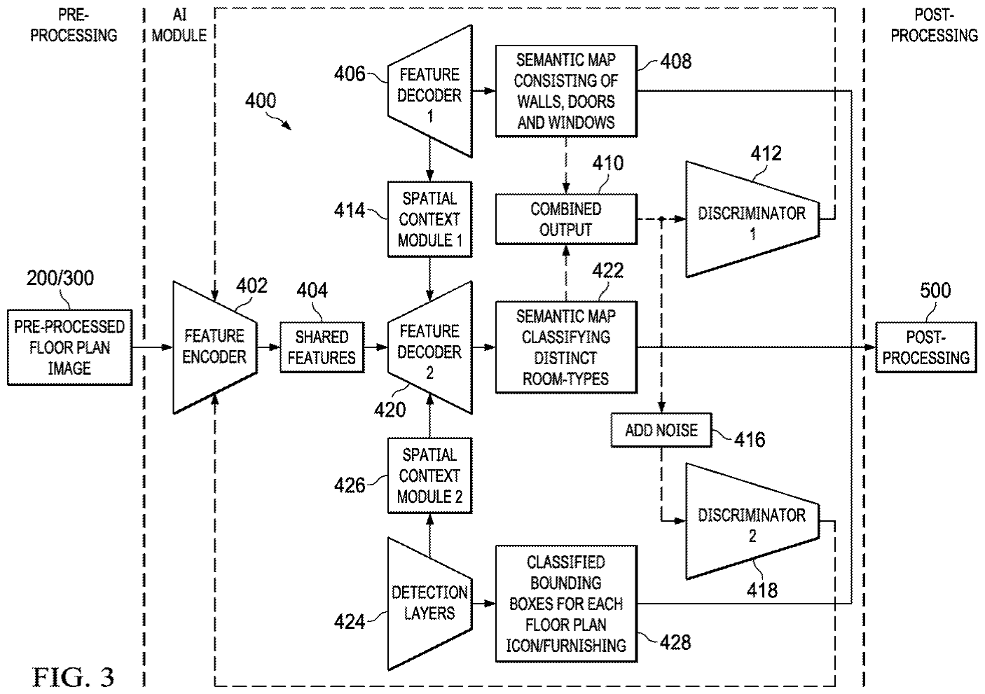

FIG. 3 provides a flowchart depicting an AI framework in accordance with an example implementation of the disclosed technology. With reference to FIG. 3, AI module 400 includes a pre-trained AI module that analyses the pre-processed floor plan image and then outputs the following: (i) bounding boxes 428 having predefined classes (e.g., furnishing, countertop, appliance) corresponding to various floor plan icons; (ii) semantic map 408 classifying walls, doors, and windows; and (iii) semantic map 422 classifying room-types (e.g., conference rooms, living areas, dining areas, kitchens, and bedrooms). Previously known systems that utilize deep learning to analyze floor plans are limited in that they can only provide one or two of the above-mentioned outputs, whereas the architecture of the disclosed technology provides all three outputs with a high degree of accuracy. Also as shown in FIG. 3, the disclosed AI architecture includes the following components: (i) feature encoder 402; (ii) spatial context modules 414 and 426; (iii) feature decoders 1 (406), and 2 (420); detection layers 424; and discriminators 1 (412) and 2 (418).

Feature encoder 402 is a combination of convolutional neural network layers that acquires an image as an input and then outputs essential features of that image. Feature encoder 402 learns and optimizes these features during training. In an example implementation, feature encoder 402 uses ResNet34 [2]. Spatial context modules 1 (414) and 2 (426) assist feature decoder 2 (420) by providing additional information on structures and furnishings from feature decoder 1 (406) and detection layers 424. Using this approach, feature decoder 2 (420) is able to provide enhanced or superior room boundaries and classifications [4][6]. Feature decoders 1 (406) and 2 (420) are also combinations of convolutional neural network layers that utilize the provided features to classify each pixel. In the example implementation of FIG. 3, feature decoder 1 (406) is used to obtain structures semantic map 408 and feature decoder 2 (420) is used to obtain rooms semantic map 422 [4]. Detection layers 424 are the final layers of the neural network that perform multi-class classification and provide classified bounding boxes 428 for all furnishings [3] [5].

The disclosed AI module is a generative adversarial network (GAN)[7] that includes both a generator network and an adversarial network. In the example implementation of FIG. 3, the generator network includes feature encoder 402, spatial context modules 1 (414) and 2 (426), detection layers 424, and feature decoders 1 (406) and 2 (420) and the adversarial network includes discriminator 1 (412) and discriminator 2 (418). Discriminator 1 (412) receives the combined output (410) of semantic map 408 and semantic map 422 and discriminator 2 (412) receives the combined output (410) of semantic map 408 and semantic map 422 as well as noise 416. The generator network makes a prediction that is close to ground truth to “fool” the adversarial network. The adversarial network attempts to distinguish between a predicted output and the ground truth. Feedback from discriminators 1 (412) and 2 (418) is provided back to the generator network for the purpose of self-improvement. Discriminators 1 (412) and 2 (418) are components of the neural network that are only used during AI model training [1][6].

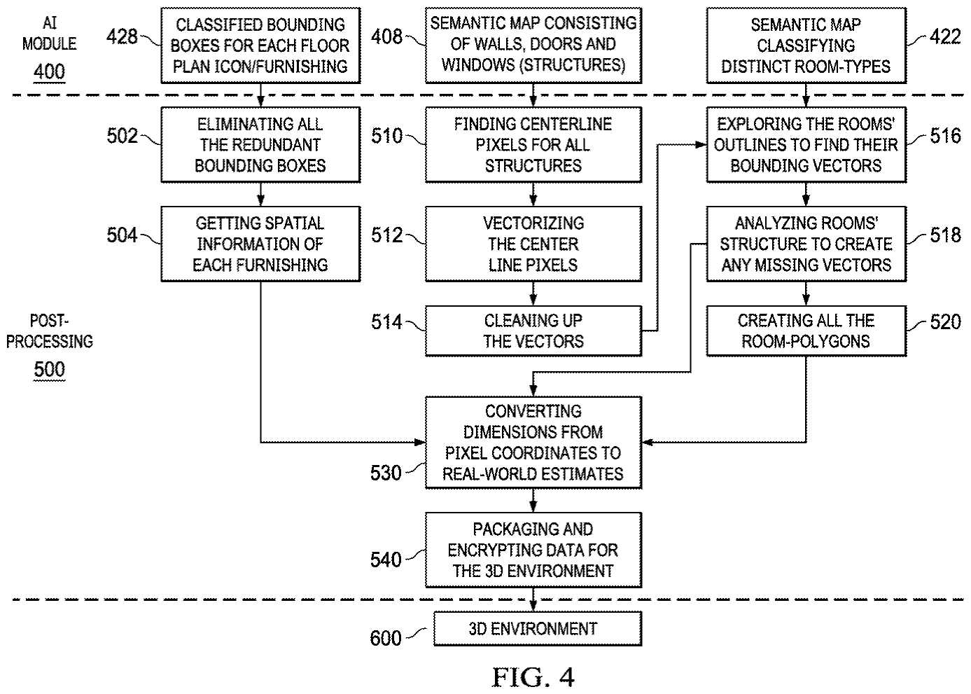

FIG. 4 provides a flowchart depicting a post-processing framework in accordance with an example implementation of the disclosed technology. Post-processing module 500 processes raw outputs such as semantic maps 408 and 422 and classified bounding boxes 428 from AI module 400 to create geometric vectors and polygons in real-world measurements for three- dimensional environment 600. An example implementation of post-processing component or module 500 includes: (i) processing classified bounding boxes for each furnishing; (ii) processing a semantic map for each structure; (iii) processing a semantic map for each room-type; (iv) converting dimensions from pixel coordinates to real-world estimates; and (v) packaging and encoding data for the three-dimensional environment.

Processing classified bounding boxes for each furnishing involves obtaining spatial information for each furnishing in terms of pixel coordinates. This process includes: (i) eliminating all the redundant bounding boxes at step 502; and (ii) obtaining spatial information for each furnishing at step 504. At step 502, all redundant bounding boxes (e.g., too small, overlapping other bounding boxes, or boxes with less confidence) are eliminated. At step 504, one pixel of an image is set as an anchor point, which is generally either the center pixel of the image or the first pixel of the image. The center point, orientation, and dimensions (height and width) of each bounding box relative to the anchor point is then calculated.

Processing a semantic map for each structure involves taking the pixels from the semantic map of all of the structures as input and providing vectors as output. This process includes: (i) finding centerline pixels for all structures at step 510; (ii) vectorizing the center lines at step 512; and (iii) cleaning up the vectors at step 514. At step 510 semantic structure map 408 is converted into multiple bitmaps representing each type of structure (walls, windows, doors, etc). Then, then following iterative process is executed: (a) using image convolution on each structure bitmap to set a score for each pixel based on its neighbors; (b) classifying all the highest scoring pixels as inner pixels and all the others as outer pixels; (c) setting any outer pixel that does not have an inner pixel neighbor as centerline pixel; and (d) removing all the outer pixels from the bitmap. This process continues until all centerline pixels of a structure are found. At step 512, each pixel from the centerline is assumed to be a graph node and a direction-aware graph search algorithm is used to find pixels from the centerline that form straight lines. This search algorithm prioritizes exploration of the pixels that are in the same direction as from the previous pixel, and any neighboring pixel different from direction from previous to current pixel would be part of a new branch. Thus, each branch explored would be a straight line of pixels. Ultimately, each of these straight lines are processed to be a vector. Step 514 includes: (a) removing any redundant vectors (duplicate vectors and vectors below a certain length threshold); (b) extending and joining vectors at their intersection if their endpoints are within a distance threshold; (c) if there is an endpoint of a vector (V1) within a certain distance of another vector (V2), splitting vector V2 into two vectors and extending vector V1 to meet at the split point of vector V2; (d) if the angle between any two joining vectors is within a set angle threshold to any of the angles in the provided angle set, moving their intersection point to form the angle from the angle set. The angle set is generally defined to [0, 45, 90, 135, 180, 225, 270, 315] degrees.

Processing a semantic map for each room-type involves using all pixels from semantic map 422 and output from vector cleaning step 514 to create room polygons. This process includes exploring the outlines of rooms to find their bounding vectors at step 516; analyzing the structure of the rooms to create any missing vectors at step 518; and creating all room polygons at step 520. At step 516, all the room pixels are separated into multiple bitmaps based on their room- types. Then, the following iterative exploration process is executed: (a) using image convolution on each room bitmap to find the pixels forming the immediate boundary of the room; (b) checking if any of the bounding pixels are a part of a vector or another room; (c) setting the relationship of the current room with any found bounding vectors or neighboring rooms; and removing any pixel that is part of the vector or another room from their room bitmap. This process is continued until the bounding walls of all the rooms are formed. At step 518, for all the rooms that were not completely enclosed, the room bitmaps are analyzed at the exploration point where the last bounding wall was found. Then, new imaginary vectors are created along the outline of the room structures at its last exploration point. Step 520 involves utilizing the vectors and imaginary vectors bounding each room to create the room-polygons for each room.

Converting dimensions from pixel coordinates to real-world estimates occurs at step 530, which involves converting spatial information for all the furnishings, structures, vectors, and room-polygons from pixel coordinates to real-world coordinates. This is done by finding some element that has a standard real world dimension (e.g., door, stove, bathtub, etc.). Packaging and encoding data for the three-dimensional environment occurs at step 540, where all the processed data is packaged into the requested format of the three-dimensional environment and encrypted with a key provided by the three-dimensional environment.

All literature and similar material cited in this application, including, but not limited to, patents, patent applications, articles, books, treatises, and web pages, regardless of the format of such literature and similar materials, are expressly incorporated by reference in their entirety. Should one or more of the incorporated references and similar materials differs from or contradicts this application, including but not limited to defined terms, term usage, described techniques, or the like, this application controls.

As previously stated and as used herein, the singular forms “a,” “an,” and “the,” refer to both the singular as well as plural, unless the context clearly indicates otherwise. The term “comprising” as used herein is synonymous with “including,” “containing,” or “characterized by,” and is inclusive or open-ended and does not exclude additional, unrecited elements or method steps. Although many methods and materials similar or equivalent to those described herein can be used, particular suitable methods and materials are described herein. Unless context indicates otherwise, the recitations of numerical ranges by endpoints include all numbers subsumed within that range. Furthermore, references to “one implementation” are not intended to be interpreted as excluding the existence of additional implementations that also incorporate the recited features. Moreover, unless explicitly stated to the contrary, implementations “comprising” or “having” an element or a plurality of elements having a particular property may include additional elements whether or not they have that property.

The terms “substantially” and “about”, if or when used throughout this specification describe and account for small fluctuations, such as due to variations in processing. For example, these terms can refer to less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%, and/or 0%.

Underlined and/or italicized headings and subheadings are used for convenience only, do not limit the disclosed subject matter, and are not referred to in connection with the interpretation of the description of the disclosed subject matter. All structural and functional equivalents to the elements of the various implementations described throughout this disclosure that are known or later come to be known to those of ordinary skill in the art are expressly incorporated herein by reference and intended to be encompassed by the disclosed subject matter.

Moreover, nothing disclosed herein is intended to be dedicated to the public regardless of whether such disclosure is explicitly recited in the above description.

There may be many alternate ways to implement the disclosed technology. Various functions and elements described herein may be partitioned differently from those shown without departing from the scope of the disclosed technology. Generic principles defined herein may be applied to other implementations. Different numbers of a given module or unit may be employed, a different type or types of a given module or unit may be employed, a given module or unit may be added, or a given module or unit may be omitted.

Regarding this disclosure, the term “a plurality of” refers to two or more than two. Unless otherwise clearly defined, orientation or positional relations indicated by terms such as “upper” and “lower” are based on the orientation or positional relations as shown in the figures, only for facilitating description of the disclosed technology and simplifying the description, rather than indicating or implying that the referred devices or elements must be in a particular orientation or constructed or operated in the particular orientation, and therefore they should not be construed as limiting the disclosed technology. The terms “connected”, “mounted”, “fixed”, etc. should be understood in a broad sense. For example, “connected” may be a fixed connection, a detachable connection, or an integral connection; a direct connection, or an indirect connection through an intermediate medium. For an ordinary skilled in the art, the specific meaning of the above terms in the disclosed technology may be understood according to specific circumstances.

It should be appreciated that all combinations of the foregoing concepts and additional concepts discussed in greater detail herein (provided such concepts are not mutually inconsistent) are contemplated as being part of the disclosed technology. In particular, all combinations of claimed subject matter appearing at the end of this disclosure are contemplated as being part of the technology disclosed herein. While the disclosed technology has been illustrated by the description of example implementations, and while the example implementations have been described in certain detail, there is no intention to restrict or in any way limit the scope of the appended claims to such detail. Additional advantages and modifications will readily appear to those skilled in the art. Therefore, the disclosed technology in its broader aspects is not limited to any of the specific details, representative devices and methods, and/or illustrative examples shown and described. Accordingly, departures may be made from such details without departing from the spirit or scope of the general inventive concept.

The following references form part of the specification of the present application and each reference is incorporated by reference herein, in its entirety, for all purposes.
[1] S. Kim et al., “Deep Floor Plan Analysis for Complicated Drawings Based on Style Transfer” Journal of Computing in Civil Engineering, 2021.
[2] K. He et al., “Deep Residual Learning for Image Recognition” Proc. in IEEE Conf. on Computer Vision and Pattern Recognition (CVPR), 2016.
[3] J. Redmon et al., “You Only Look Once: Unified, Real-Time Object Detection” Proc. in IEEE Conf. on Computer Vision and Pattern Recognition (CVPR), 2016.
[4] Z. Zeng et al., “Deep Floor Plan Recognition Using a Multi-Task Network with Room-Boundary-Guided Attention” Proc. in IEEE Conf. on Computer Vision and Pattern Recognition (CVPR), 2019.
[5] A. Rezvanifar et al., “Symbol Spotting on Digital Architectural Floor Plans Using a Deep Learning-based Framework” Proc. in IEEE Conf. on Computer Vision and Pattern Recognition (CVPR), 2020.
[6] Y. Zhang et al., “The Direction-Aware, Learnable, Additive Kernels and the Adversarial Network for Deep Floor Plan Recognition” arXiv, 2020.
[7] I. J. Goodfellow et al., “Generative Adversarial Nets” Advances in Neural Information Processing Systems, 2014.

What is claimed:

1. A system for creating three-dimensional environments from two-dimensional images, comprising:
(a) a pre-processing component configured to receive an input of a two-dimensional image of a floorplan, resize the image, normalize the image, and then generate an output of the image;
(b) an artificial intelligence component configured to receive the output of the pre-processing component and generate bounding boxes having predefined classes of items corresponding to various floorplan icons; a semantic map classifying room structures; and
a semantic map classifying room types, and then generate an output of the bounding boxes and semantic maps; and
(c) a post-processing component configured to receive the output of the artificial intelligence component and process the classified bounding boxes for each predefined class of item; process the semantic map for each structure; process the semantic map for each room-type; convert dimensions from pixel coordinates to real-world estimates; package and encode data for a three-dimensional environment; and then generate an output of the three-dimensional environment.

2. The system of claim 1, wherein the artificial intelligence component includes a generative adversarial neural network that further includes both a generator network and an adversarial network.

3. The system of claim 2, wherein the generator network includes a feature encoder, first and second spatial context modules, detection layers, and first and second feature decoders.

4. The system of claim 2, wherein the adversarial network includes first and second discriminators.

5. The system of claim 1,
(a) wherein the predefined classes of items corresponding to various floorplan icons include furnishings, countertops, and appliances;
(b) wherein the room structures include walls, doors, and windows; and
(c) wherein the room types include offices, conference rooms, living areas, dining areas, kitchens, and bedrooms.

6. The system of claim 1, wherein the post-processing component creates geometric vectors and polygons in real-world measurements for the three-dimensional environment.

7. The system of claim 1,
(a) wherein processing classified bounding boxes for each predefined class of item includes obtaining spatial information for each predefined class of item in terms of pixel coordinates;
(b) wherein processing a semantic map for each room structure includes taking the pixels from the semantic map of all of the structures as input and providing vectors as output;
(c) wherein processing a semantic map for each room type includes using all pixels from the semantic map of all the room-types and the vectors from the semantic maps of each structure and creating room polygons; and
(d) wherein converting dimensions from pixel coordinates to real-world estimates includes converting spatial information for all the predefined classes, structures, vectors, and room-polygons from pixel coordinates to real-world coordinates.

8. A method for creating three-dimensional environments from two-dimensional images, comprising:
(a) inputting a two-dimensional image of a floorplan into a pre-processing component, wherein the pre-processing component resizes the image, normalizes the image, and then generates an output of the image;
(b) inputting the output of the pre-processing component into an artificial intelligence component, wherein the artificial intelligence component generates bounding boxes having predefined classes of items corresponding to various floorplan icons; a semantic map classifying room structures; and a semantic map classifying room types, and then generates an output of the bounding boxes and semantic maps; and
(c) inputting the output of the artificial intelligence component into a post-processing component, wherein the post-processing component processes the classified bounding boxes for each predefined class of item; processes the semantic map for each structure;
processes the semantic map for each room-type; converts dimensions from pixel coordinates to real-world estimates; packages and encodes data for a three-dimensional environment; and then generates an output of the three-dimensional environment.

9. The method of claim 8, wherein the artificial intelligence component includes a generative adversarial neural network that further includes both a generator network and an adversarial network.

10. The method of claim 9, wherein the generator network includes a feature encoder, first and second spatial context modules, detection layers, and first and second feature decoders, and wherein the adversarial network includes first and second discriminators.

11. The method of claim 8,
(a) wherein the predefined classes of items corresponding to various floorplan icons include furnishings, countertops, and appliances;
(b) wherein the room structures include walls, doors, and windows; and
(c) wherein the room types include offices, conference rooms, living areas, dining areas, kitchens, and bedrooms.

12. The method of claim 8, wherein the post-processing component creates geometric vectors and polygons in real-world measurements for the three-dimensional environment.

13. The method of claim 8,
(a) wherein processing classified bounding boxes for each predefined class of item includes obtaining spatial information for each predefined class of item in terms of pixel coordinates;
(b) wherein processing a semantic map for each room structure includes taking the pixels from the semantic map of all of the structures as input and providing vectors as output;
(c) wherein processing a semantic map for each room type includes using all pixels from the semantic map of all the room-types and the vectors from the semantic maps of each structure and creating room polygons; and
(d) wherein converting dimensions from pixel coordinates to real-world estimates includes converting spatial information for all the predefined classes, structures, vectors, and room-polygons from pixel coordinates to real-world coordinates.

14. A method for creating three-dimensional environments from two-dimensional images, comprising:
(a) inputting a two-dimensional image of a floorplan into a pre-processing component, wherein the pre-processing component resizes the image, normalizes the image, and then generates an output of the image;
(b) inputting the output of the pre-processing component into an artificial intelligence component, wherein the artificial intelligence component generates bounding boxes having predefined classes of items corresponding to various floorplan icons; a semantic map classifying room structures; and a semantic map classifying room-types, and then generates an output of the bounding boxes and semantic maps,
(i) wherein the artificial intelligence component includes a generative adversarial neural network that includes a generator network having a feature encoder, first and second spatial context modules, detection layers, and first and second feature decoders, and an adversarial network having first and second discriminators; and
(c) inputting the output of the artificial intelligence component into a post-processing component, wherein the post-processing component processes the classified bounding boxes for each predefined class of item; processes the semantic map for each structure;
processes the semantic map for each room-type; converts dimensions from pixel coordinates to real-world estimates; packages and encodes data for a three-dimensional environment; and then generates an output of the three-dimensional environment.

15. The method of claim 14,
(a) wherein the predefined classes of items corresponding to various floorplan icons include furnishings, countertops, and appliances;
(b) wherein the room structures include walls, doors, and windows; and
(c) wherein the room types include offices, conference rooms, living areas, dining areas, kitchens, and bedrooms.

16. The method of claim 14, wherein the post-processing component creates geometric vectors and polygons in real-world measurements for the three-dimensional environment.

17. The method of claim 14, wherein processing classified bounding boxes for each predefined class of item includes obtaining spatial information for each predefined class of item in terms of pixel coordinates.

18. The method of claim 14, wherein processing a semantic map for each room structure includes taking the pixels from the semantic map of all of the structures as input and providing vectors as output.

19. The method of claim 14, wherein processing a semantic map for each room type includes using all pixels from the semantic map of all the room-types and the vectors from the semantic maps of each structure and creating room polygons.

20. The method of claim 14, wherein converting dimensions from pixel coordinates to real-world estimates includes converting spatial information for all the predefined classes, structures, vectors, and room-polygons from pixel coordinates to real-world coordinates.
